(19) United States
(12) Patent Application Publication
(10) Pub. No.: US 2019/0010079 A1
(43) Pub. Date: Jan. 10, 2019

(54) Fluorescent Glass For Light Emitting Diode And Manufacturing Method Thereof

(71) Applicants: Platinum Optics Technology (Suzhou) Inc., Suzhou (CN); Platinum Optics Technology Inc., Taoyuan City (TW)

(72) Inventors: Chun-Yuan Lu, Taoyuan City (TW); Yi-Yao Liao, Taoyuan City (TW); Chun-Teng Lin, Taoyuan City (TW)

(21) Appl. No.: 15/816,167

(22) Filed: Nov. 17, 2017

(30) Foreign Application Priority Data
Jul. 4, 2017 (CN) 201710536022.3

(51) Int. Cl. C03C 4/12; H01L 33/50; C09K 11/02; C03C 14/00; C03C 3/064; C03B 19/06

(52) U.S. Cl. CPC C03C 4/12; H01L 33/502; H01L 33/507; H01L 2933/0041; C03C 14/004; C03C 3/064; C03B 19/06; C09K 11/025

(57) ABSTRACT

The present disclosure is related to a fluorescent glass for a light emitting diode and a manufacturing method thereof. The fluorescent glass for the light emitting diode includes a glass powder and a fluorescent powder, wherein the glass powder and the fluorescent powder are mixed to form a fluorescent glass, the material for manufacturing the glass powder comprises silicon dioxide with 20 wt % to 37 wt %, diboron trioxide with 31 wt %-47 wt % and calcium oxide with 16 wt %˜35 wt %, and the material of the fluorescent powder is selected from one of Ce-YAG, LuAG, silicate, and nitrides/oxynitrides fluorescent powder. The fluorescent glass of the present disclosure is formed by mixing and sintering the glass powder and the fluorescent powder and has low sintering temperature, so as to avoid the deterioration of color of the fluorescent powder due to high temperature. Therefore, the fluorescent glass of the present disclosure has good transparency, and the light emitting diode applying this fluorescent glass has good lighting efficiency.

### CROSS REFERENCE TO RELATED APPLICATION

This application claims the priority benefit of China Patent Application Serial Number 201710536022.3, filed on Jul. 4, 2017, the full disclosure of which is incorporated herein by reference.

### BACKGROUND

### Technical Field

The present disclosure generally relates to a fluorescent glass and, more particularly, to a fluorescent glass for a light emitting diode and a manufacturing method thereof.

### Related Art

Currently, the white light emitting diode is formed by mixing and coating the fluorescent powder and the polymer silicone on a blue light chip. The blue light chip lights to excite the fluorescent powder, so as to generate yellow light, and the yellow light and the blue light is mixed to form the white light. However, under the state of long time and high temperature, the silicone in the white light emitting diode easily generate yellowing and deterioration, thereby affecting the lighting effect of the white light emitting diode. Currently, the above problem is solved by the white light emitting diode using the fluorescent glass, the fluorescent glass is formed by coating the fluorescent powder layer on the surface of the glass sheet, and most of the material of the glass sheet is lead or lead-free alkali glass, for example, SiO₂—B2O₃ series or P₂O₅ series adds alkali metal oxide, such as Na, K, Li, etc.

If the above glass sheet applies the alkali-free glass, the alkali-free glass does not contain the glass with alkali metal oxide. However, it does not add the alkali metal and has silicon dioxide with high content. It needs the high temperature for melting. The melting temperature is above 1500° C. and a time of this high temperature keeps for hours or ten hours, such that the component of the alkali-free glass is melted and homogeneous to form a melted glass. The viscosity of the melted glass is high and the flowability of the melted glass is poor, such that the subsequent process thereof is relatively difficult to operate. Additionally, the coefficient of the thermal expansion of this glass is about 3.0×10⁻⁶ to 4.0×10⁻⁶, the coefficient of the thermal expansion of the fluorescent powder is about 8.0×10⁻⁶. The difference between the coefficient of the thermal expansion of the glass and the coefficient of the thermal expansion of the fluorescent powder is large. The sintering temperature needs higher when the glass and the fluorescent powder are sintered, such that a stress is easily generated when sintering, and the subsequent manufacturing of the fluorescent glass is not easy.

This prior art discribed in this section is merely to assist in understanding the present disclosure. The content disclosed in this section may contain some prior art that is not known to those skilled in the art. The content disclosed by this section does not represent the content or the problem to be solved by one or more embodiments of the present disclosure that is known or recognized by those of ordinary skill in the art before filing the present disclosure.

### SUMMARY

A purpose of the present disclosure is to provide a fluorescent glass for a light emitting diode and a manufacturing method thereof. The fluorescent glass for the light emitting diode is formed by mixing and sintering a glass powder and a fluorescent powder, and the fluorescent powder is distributed on a glass medium. When the fluorescent glass of the present disclosure is applied to the light emitting diode, a light generated by a chip of light emitting diode may directly pass through the glass medium and excites the fluorescent powder distributed on the glass medium. Therefore, the light loss in the transmission process is avoided and the lighting efficiency of the light emitting diode is effectively improved.

Another purpose of the present disclosure is to provide a fluorescent glass for a light emitting diode and a manufacturing method thereof, wherein the material for manufacturing the glass powder has a low silicon content and a high boron content. The temperature for melting the above material may be controlled below 1400° C., such that the melted glass has good flowability for subsequent processing.

Yet another purpose of the present disclosure is to provide a fluorescent glass for a light emitting diode and a manufacturing method thereof, wherein the coefficient of thermal expansion of the glass powder is similar to the coefficient of the thermal expansion of the fluorescent powder, such that the temperature for mixing and sintering the glass powder and fluorescent powder may be controlled. Therefore, occurrence of the deterioration of color of the fluorescent powder resulted from the high sintering temperature and affecting the transparency of the fluorescent glass ingot is avoided such that the lighting efficiency of the light emitting diode would not be affected.

The present disclosure provides a fluorescent glass for a light emitting diode, which includes a glass powder and a fluorescent powder, wherein the glass powder and the fluorescent powder are mixed to form a fluorescent glass, the material for manufacturing the glass powder comprises silicon dioxide with 20 wt % to 37 wt %, diboron trioxide with 31 wt %-˜47 wt % and calcium oxide with 16 wt %˜35 wt %, and the material of the fluorescent powder is selected from one of Ce-YAG, LuAG, silicate, and nitrides/oxynitrides fluorescent powder.

The present disclosure further provides manufacturing method of a fluorescent glass for a light emitting diode, which includes: providing the material for manufacturing a glass powder, wherein the material for manufacturing the glass powder comprises silicon dioxide with 20 wt % to 37 wt %, diboron trioxide with 31 wt %˜47 wt % and calcium oxide with 16 wt %˜35 wt %; melting the material for manufacturing the glass powder to form a melted glass, wherein a melting temperature is below 1400° C.; injecting the melted glass to water for quenching, so as to obtain a glass sand; grinding the glass sand into the glass powder; mixing the glass powder and a fluorescent powder and pressing the glass powder and the fluorescent powder into a fluorescent glass embryo, wherein the material of the fluorescent powder is selected from one of Ce-YAG, LuAG, silicate, and nitrides/oxynitrides fluorescent powder; sintering the fluorescent glass embryo into a fluorescent glass ingot, wherein a sintering temperature is between 750° C. and 850° C.; and cutting the fluorescent glass ingot into at least one fluorescent glass with sheet shape.

It should be understood, however, that this summary may not contain all aspects and embodiments of the present invention, that this summary is not meant to be limiting or restrictive in any manner, and that the invention as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a flowchart of a manufacturing method of a fluorescent glass for a light emitting diode according to an embodiment of the present disclosure.

### DETAILED DESCRIPTION OF THE EMBODIMENTS

The present disclosure will now be described more fully hereinafter with reference to the accompanying drawings, in which exemplary embodiments of the invention are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

Firstly, the present disclosure provides a fluorescent glass for a light emitting diode and a manufacturing method therefore, the material of fluorescent glass for the light emitting diode includes a glass powder and a fluorescent powder, the glass powder and a fluorescent powder are mixed and pressed into a fluorescent glass embryo, and the fluorescent glass embryo is sintered, so as to form the fluorescent glass for the light emitting diode. As mentioned above, in the fluorescent glass of the present disclosure, the fluorescent powder is distributed on the glass and does not form a fluorescent powder layer on the surface of the glass. When the light emitting diode using the fluorescent glass of the present disclosure lights, the light directly enters the fluorescent glass and excites the fluorescent powder in the fluorescent glass. On the contrary, when the light emitting diode using the prior fluorescent glass lights, the light passes through the glass medium firstly, and enters the fluorescent powder layer and excites the fluorescent powder in the fluorescent powder layer. Therefore, the light generated by the chip of the light emitting diode by using the fluorescent glass of the present disclosure may fully excite the fluorescent powder. It does not occur the loss when the light passes through the glass medium. Therefore, the lighting efficiency of the light emitting diode applying the fluorescent glass of the present disclosure is high.

The materials of the glass powder and the fluorescent powder used by the fluorescent glass of the present disclosure are described in details as follows. The material for manufacturing the glass powder includes silicon dioxide with 20 wt % to 37 wt %, diboron trioxide with 31 wt %˜47 wt % and calcium oxide with 16 wt %˜35 wt %. Silicon dioxide and diboron trioxide are the primary component for manufacturing the glass powder. Silicon dioxide may increase the structural stability of the formed glass thereof, decrease the coefficient of the thermal expansion of the glass and improve the thermal shock stability, chemical stability and mechanical strength of the glass. Diboron trioxide decrease a melting temperature for forming the glass and may decrease the viscosity of the glass. Calcium oxide may also decrease the viscosity of the glass, such that the glass is easy to melt and homogeneous. The content of silicon dioxide of the material for manufacturing the glass powder of the present disclosure is less than the content of silicon dioxide of the current glass for the light emitting diode, the content of diboron trioxide thereof is higher than the content of diboron trioxide of the glass for the light emitting dioce, and the melting temperature of the material for manufacturing the glass powder of the present disclosure is below 1400° C. The material of the above fluorescent powder is selected from one of Ce-YAG, LuAG, silicate, and nitrides/oxynitrides fluorescent powder.

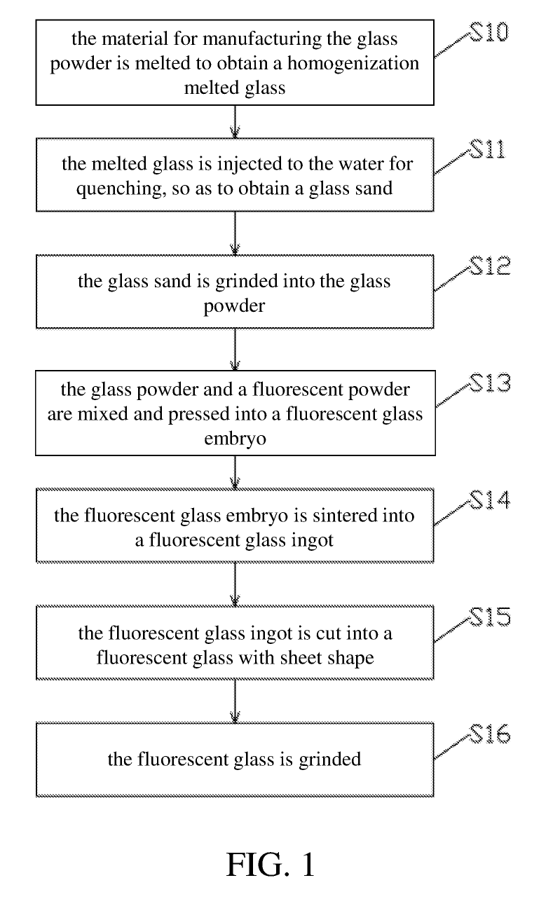

Refer to FIG. 1. FIG. 1 is a flowchart of a manufacturing method of a fluorescent glass for a light emitting diode according to an embodiment of the present disclosure. As shown in FIG. 1, step S10 is firstly performed, in which the above material for manufacturing the glass powder is melted. The above material for manufacturing the glass powder is placed in a crucible, and the crucible containing the above material for manufacturing the glass powder is placed in a furnace containing an atmosphere or a reducing atmosphere to melt, so as to obtain a homogenization melted glass, wherein the melting temperature is below 1400° C. The viscosity of the melted glass is not high, such that the melted glass has good flowability. Then Step S11 is performed, in which the melted glass is injected to the water for quenching, so as to obtain a glass sand. Since the flowability of the melted glass is good, the melted glass is easy to inject to the water. The problem of the melted glass that can not be injected to the water for quenching because the of higher viscosity or poor flowability of melted glass may be solved. The coefficient of the thermal expansion of the glass sand is between 5×10⁻⁶ and 7.6×10⁻⁶, the glass converting temperature (Tg) of the glass sand is between 620° C. and 675° C., and the softening temperature (Ts) of the glass sand is between 660° C. and 730° C. Then Step S12 is performed, in which the glass sand is grinded into the glass powder, wherein the particle size of the glass powder is smaller than 100 μm. Since the content of silicon dioxide of the material for manufacturing is fewer, the hardness of the glass sand is not high, such that the glass sand is easily grinded into powder. Then Step S13 is performed, in which the glass powder and a fluorescent powder are mixed and pressed into a fluorescent glass embryo, and there is a good adhesion between the glass powder and the fluorescent powder, so as to avoid the fluorescent glass embryo easy to crack. Then Step S14 is performed, in which the fluorescent glass embryo is sintered into a fluorescent glass ingot, and a sintering temperature thereof is between 750° C. and 850° C. Since the coefficient of the thermal expansion of the glass sand is between 5×10⁻⁶ and 7.6×10⁻⁶, the sintering temperature of the glass powder and the fluorescent powder may be decreased, and the deterioration of color of the fluorescent powder that may affect the transparency of the fluorescent glass ingot is avoided through the low temperature sintering. Then Step S15 is performed, in which the fluorescent glass ingot is cut into a fluorescent glass with sheet shape. Then Step S16 is performed, in which the fluorescent glass is grinded, wherein the thickness of the fluorescent glass is between 120 μm and 200 μm. Finally, the grinded fluorescent glass may be cut to a fluorescent glass sheet with length and width dimensions as 1 mm×1 mm, and the fluorescent glass sheet is attached to a blue light emitting diode chip to form an element and then perform the optical quality measurement.

The material for manufacturing the glass powder of the present disclosure further includes magnesium oxide or zinc oxide, and the weight percent of magnesium oxide or zinc oxide is between 0 wt % and 17 wt %. Magnesium oxide or zinc oxide is added to increase the stability and weatherability of the glass formed by this material and decrease the coefficient of the thermal expansion of the glass. The material for manufacturing the glass powder of the present disclosure further includes aluminum oxide. The weight percent of the aluminum oxide is between 0 wt % and 12 wt %. It may increase thermal stability, mechanical strength and refractive index of the glass.

As mentioned above, the composition of the material for manufacturing the glass powder of the present disclosure may form the melted glass at a melting temperature below 1400° C., the viscosity of the melted glass is not high and the melted glass has good flowablility, so as to easily perform the subsequent process, such quenching, grinding, sintering, cutting, etc. Although the viscosity of the glass powder formed by the above material is not high, the stickiness still exists between the glass powder and the fluorescent powder when the glass powder and the fluorescent powder are mixed and pressed, such that the fluorescent glass embryo is not easy to crack before sintering. However, the coefficient of the thermal expansion of the glass powder is similar to the coefficient of the thermal expansion of the fluorescent powder, the sintering temperature of the glass powder and the fluorescent powder is controlled between 750° C. and 850° C., so as to avoid the deterioration of color of the fluorescent powder resulted in affecting the transparency of the fluorescent glass ingot. The fluorescent glass formed by cutting the fluorescent glass ingot has good transparency and improves the lighting efficiency of the fluorescent glass as the light emitting diode.

Six embodiments are provided as follows. The glass sand in each embodiment is manufactured by the above material for manufacturing the glass powder, and a list of the material composition and properties thereof of the glass sand of each embodiment is provided. The following table shows that the melting temperature of the glass sand of each embodiment is between 1250° C. and 1400° C. to ensure that the melting temperature for manufacturing the glass sand of the present disclosure may be controlled below 1400° C. The following table shows that the coefficient of the thermal expansion of the glass sand of each embodiment is between 5×10⁻⁶ and 7.6×10⁻⁶. It may control the sintering temperature of the glass powder and the fluorescent powder after grinding the glass sand. The glass powder generated by grinding the glass sand in each following embodiment and the fluorescent powder may be sintered to form the fluorescent glass with glass luster, and it also indicates that the fluorescent powder may not have the deterioration of color that would affect the luminescence of the fluorescent glass. It also ensures that when the fluorescent glass formed by sintering the glass powder generated by grinding the glass sand in the following embodiment and the fluorescent powder is applied to the light emitting diode. It may greatly improve the lighting efficiency of the light emitting diode.

| Embodiment | 1 | 2 | 3 | 4 | 5 | 6 |
|---|---|---|---|---|---|---|
| silicon dioxide | 24.5 | 28 | 33.5 | 22.5 | 21 | 20.6 |
| diboron | 43 | 38 | 42.5 | 39 | 31.8 | 36.5 |
| trioxide | | | | | | |
| calcium oxide | 32.5 | 17 | 23 | 22.5 | 20.7 | 16.9 |
| magnesium | — | 17 | — | — | — | |
| oxide | | | | | | |
| zinc oxide | — | — | — | 16 | 14.5 | 14.5 |
| aluminum | — | — | — | — | 12 | 11.5 |
| oxide | | | | | | |
| glass | 648 | 672 | 659 | 622 | 624 | 621 |
| converting | | | | | | |
| temperature | | | | | | |
| (Tg) | | | | | | |
| Softening | 687 | 727 | 712 | 666 | 675 | 662 |
| temperature | | | | | | |
| (Ts) | | | | | | |
| Coefficient of | 7.52 | 5.17 | 5.5 | 6.85 | 6.82 | 6.48 |
| thermal | | | | | | |
| expansion | | | | | | |
| (CTE) | | | | | | |
| Melting | 1300 | 1400 | 1350 | 1250 | 1400 | 1400 |
| temperature | | | | | | |

In summary, the present disclosure discloses a fluorescent glass for a light emitting diode and a manufacturing method thereof, the fluorescent glass for the light emitting diode is formed by mixing and sintering the glass powder and the fluorescent powder, and the fluorescent powder is distributed on the glass medium. When the fluorescent glass is applied to the light emitting diode, the light generated by the chip of light emitting diode may directly pass through the glass medium and excites the fluorescent powder distributed on the glass medium. Therefore, the light loss in the transmission process is avoided and the lighting efficiency of the light emitting diode is effectively improved. Additionally, the material for manufacturing the glass powder of the present disclosure has the low silicon content and the high boron content, and the temperature for melting the above material may be controlled below 1400° C., such that the melted glass has good flowability for subsequent processing. The coefficient of thermal expansion of the glass powder formed by the above material is similar to the coefficient of the thermal expansion of the fluorescent powder, such that the temperature for mixing and sintering the glass powder and fluorescent powder may be controlled. Therefore, the sintering temperature higher resulted in occurring the deterioration of color of the fluorescent powder and affecting the transparency of the fluorescent glass ingot is avoided, so as to affect the lighting efficiency of the light emitting diode.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the invention. Accordingly, such modifications are considered within the scope of the invention as limited solely by the appended claims.

What is claimed is:

1. A fluorescent glass for a light emitting diode, comprising a glass powder and a fluorescent powder, wherein the glass powder and the fluorescent powder are mixed to form a fluorescent glass, the material for manufacturing the glass powder comprises silicon dioxide with 20 wt % to 37 wt %, diboron trioxide with 31 wt %˜47 wt % and calcium oxide with 16 wt %˜35 wt %, and the material of the fluorescent powder is selected from one of Ce-YAG, LuAG, silicate, and nitrides/oxynitrides fluorescent powder.

2. The fluorescent glass for the light emitting diode as claimed in claim 1, wherein the material for manufacturing the glass powder further comprises magnesium oxide or zinc oxide, the weight percent of magnesium oxide or zinc oxide is between 0 wt % and 17 wt %.

3. The fluorescent glass for the light emitting diode as claimed in claim 2, wherein the material for manufacturing the glass powder further comprises aluminum oxide, the weight percent of the aluminum oxide is between 0 wt % and 12 wt %.

4. A manufacturing method of a fluorescent glass for a light emitting diode, comprising:
providing the material for manufacturing a glass powder, wherein the material for manufacturing the glass powder comprises silicon dioxide with 20 wt % to 37 wt %, diboron trioxide with 31 wt %˜47 wt % and calcium oxide with 16 wt %˜35 wt %;
melting the material for manufacturing the glass powder to form a melted glass, wherein a melting temperature is below 1400° C.;
injecting the melted glass to water for quenching, so as to obtain a glass sand;
grinding the glass sand into the glass powder;
mixing the glass powder and a fluorescent powder and pressing the glass powder and the fluorescent powder into a fluorescent glass embryo, wherein the material of the fluorescent powder is selected from one of Ce-YAG, LuAG, silicate, and nitrides/oxynitrides fluorescent powder;
sintering the fluorescent glass embryo into a fluorescent glass ingot, wherein a sintering temperature is between 750° C. and 850° C.; and
cutting the fluorescent glass ingot into at least one fluorescent glass with sheet shape.

5. The manufacturing method of the fluorescent glass for the light emitting diode as claimed in claim 4, wherein the material for manufacturing the glass powder further comprises magnesium oxide or zinc oxide, the weight percent of magnesium oxide or zinc oxide is between 0 wt % and 17 wt %.

6. The manufacturing method of the fluorescent glass for the light emitting diode as claimed in claim 5, wherein the material for manufacturing the glass powder further comprises aluminum oxide, the weight percent of the aluminum oxide is between 0 wt % and 12 wt %.

7. The manufacturing method of the fluorescent glass for the light emitting diode as claimed in claim 4, wherein the coefficient of thermal expansion of the glass sand is between 5×10⁻⁶ and 7.6×10⁻⁶.

8. The manufacturing method of the fluorescent glass for the light emitting diode as claimed in claim 4, wherein the particle size of the glass powder is smaller than 100 μm.

9. The manufacturing method of the fluorescent glass for the light emitting diode as claimed in claim 4, wherein the melting temperature is between 1250° C. and 1400° C.

10. The manufacturing method of the fluorescent glass for the light emitting diode as claimed in claim 4, wherein the thickness of each of the fluorescent glasses is between 120 μm and 200 μm.
